(19) United States
(12) Patent Application Publication
(10) Pub. No.: US 2025/0275398 A1
(43) Pub. Date: Aug. 28, 2025

(54) DISPLAY APPARATUS AND METHOD OF MANUFACTURING THE SAME

(71) Applicant: Samsung Display Co., Ltd., Yongin-Si (KR)

(72) Inventors: Dongeun Lee, Yongin-si (KR); Simhee Ryu, Yongin-si (KR); Kitae Ma, Yongin-si (KR); Kwangho Lee, Yongin-si (KR)

(21) Appl. No.: 18/985,057

(22) Filed: Dec. 18, 2024

(30) Foreign Application Priority Data
Feb. 22, 2024 (KR) 10-2024-0026035

(51) Int. Cl. H10K 59/131; H10K 59/12; H10K 59/80; H10K 102/00

(52) U.S. Cl. CPC H10K 59/131; H10K 59/1201; H10K 59/871; H10K 2102/311

(57) ABSTRACT

A display apparatus for reducing a visible area of a non-display area is disclosed that includes a display panel which comprises a first area, a second area, and a bending area between the first area and the second area, a first pixel arranged in the first area, and a second pixel arranged in the bending area. The display panel further comprises a first panel surface and a second panel surface that is at an opposite side to the first panel surface, the display panel is bent in the bending area with respect to a bending axis extending in a first direction, and the second panel surface in the first area is arranged to face the second panel surface in the second area.

### CROSS-REFERENCE TO RELATED APPLICATION

This application is based on and claims priority under 35 U.S.C. § 119 to Korean Patent Application No. 10-2024-0026035, filed on Feb. 22, 2024, in the Korean Intellectual Property Office, the disclosure of which is incorporated by reference herein in its entirety.

### BACKGROUND

### 1. Field

The present disclosure relates to a display apparatus which reduces a visible area of a non-display area and a method of manufacturing the same.

### 2. Description of the Related Art

A display apparatus can be used as various electronic devices. For example, the display apparatus may be a mobile electronic device such as a smartphone. The display apparatus may have a display area and a non-display area. The display area may provide an image, and a plurality of pixels may be arranged in the display area to provide the image. The non-display area may be arranged outside the display area and the non-display area may include connection lines which transmit electrical signals from a driving portion to the pixels. In order to decrease a visible area of the non-display area, a portion of a display panel may be bent.

### SUMMARY

The present disclosure includes a display apparatus reducing a visible area of a non-display area and a method of manufacturing the same. However, this feature of the present disclosure is an example and does not limit the scope of the disclosure.

Additional aspects will be set forth in the description which follows and will be apparent from the description.

According to an embodiment, a display apparatus includes a display panel which comprises a first area, a second area, a bending area between the first area and the second area, a first pixel arranged in the first area, and a second pixel arranged in the bending area, wherein the display panel further comprises a first panel surface and a second panel surface that is at an opposite side to the first panel surface, the display panel is bent in the bending area with respect to a bending axis extending in a first direction, and the second panel surface in the first area is arranged to face the second panel surface in the second area.

The display panel may further include a pad portion arranged in the second area, a connection line electrically connecting the first pixel and the second pixel to the pad portion, and the connection line may be arranged in the second area.

A radius of curvature of the bending area may be in a range of about 0.2 mm to about 0.4 mm.

The display apparatus may further comprise a first lower protective layer arranged on the second panel surface in the first area, and a second lower protective layer arranged on the second panel surface in the second area.

An end of the second lower protective layer may be in contact with the bending area.

An end of the second lower protective layer adjacent to the bending area may be spaced apart from the bending area.

The second lower protective layer may not be disposed on the second panel surface in a portion of the second area adjacent to the bending area.

The display apparatus may further comprise a lower cover panel disposed below the first lower protective layer, and a spacer disposed below the lower cover panel.

The bending area, the first lower protective layer, the lower cover panel, the spacer, and the second lower protective layer may define a space.

The display apparatus may further comprise a filling member filling the space.

The display apparatus may further comprise a cover window disposed above the display panel, an optical functional layer disposed between the display panel and the cover window, and an adhesive layer disposed between the optical functional layer and the cover window.

According to an embodiment, a method of manufacturing a display apparatus includes preparing a display panel including a first area, a second area, a bending area between the first area and the second area, a first pixel arranged in the first area, and a second pixel arranged in the bending area, and bending the display panel in the bending area with respect to a bending axis extending in a first direction, wherein the display panel further comprises a first panel surface and a second panel surface that is at an opposite side to the first panel surface, and the second panel surface in the first area faces the second panel surface in the second area after bending the display panel.

The display panel manufactured by a method according to an embodiment may further comprise a pad portion arranged in the second area and a connection line electrically connecting the first pixel and the second pixel to the pad portion, and the connection line may be arranged in the second area.

A radius of curvature of the bending area may be in a range of about 0.2 mm to about 0.4 mm after bending the display panel.

The display panel manufactured by a method according to an embodiment may further comprise a first lower protective layer attached to the second panel surface in the first area, and a second lower protective layer attached to the second panel surface in the second area.

An end of the second lower protective layer may be in contact with the bending area.

An end of the second lower protective layer adjacent to the bending area may be spaced apart from the bending area.

The second lower protective layer may not be disposed on the second panel surface in a portion of the second area adjacent to the bending area.

The display panel manufactured by a method according to an embodiment may further comprise a lower cover panel attached below the first lower protective layer, and a spacer attached below the lower cover panel.

The method may further comprise filling a space defined by the bending area, the first lower protective layer, the lower cover panel, the spacer, and the second lower protective layer with a material for forming a filling member, and irradiating ultraviolet rays to the material for forming the filling member.

The display panel manufactured by a method according to an embodiment may further comprise an optical functional layer attached onto the display panel, and a cover window attached to the optical functional layer by an adhesive layer.

### BRIEF DESCRIPTION OF THE DRAWINGS

The above and other aspects, features, and advantages of the present disclosure will become more apparent with reference to the following description taken in conjunction with the accompanying drawings.

FIG. 1 is a schematic perspective view illustrating an unbent appearance of a display apparatus according to an embodiment.

FIG. 2 is a schematic perspective view illustrating a bent appearance of a display apparatus according to an embodiment.

FIG. 3 is a schematic cross-sectional view of the display apparatus of FIG. 2, taken along a line I-I′.

FIG. 4 is a schematic plan view illustrating an unbent appearance of a display panel included in a display apparatus, according to an embodiment.

FIG. 5 is an equivalent circuit diagram of a pixel included in the display panel of FIG. 4.

FIG. 6 is a schematic cross-sectional view of a display panel of FIG. 4, taken along a line II-II′.

FIG. 7 is a schematic cross-sectional view of a display panel of FIG. 4, taken along a line III-III′.

FIG. 8 is a schematic rear view of a display apparatus according to an embodiment.

FIG. 9 is a schematic cross-sectional view of a display apparatus according to an embodiment.

FIG. 10 is a schematic cross-sectional view of a display apparatus according to an embodiment.

FIG. 11 is a schematic cross-sectional view of a display apparatus according to an embodiment.

FIGS. 12 and 13 are schematic cross-sectional views illustrating a part of a process of manufacturing the display apparatus of FIG. 3.

FIG. 14 is a schematic cross-sectional view illustrating a part of a process of manufacturing the display apparatus of FIG. 9.

FIGS. 15 and 16 are schematic cross-sectional views illustrating a part of a process of manufacturing the display apparatus of FIG. 10.

FIG. 17 is a schematic cross-sectional view illustrating a part of a process of manufacturing the display apparatus of FIG. 11.

### DETAILED DESCRIPTION

Hereinafter, specific embodiments of the present disclosure are explained in detail with reference to the accompanying drawings. Like numerals refer to like elements throughout. In this regard, the embodiments of the present disclosure may have different forms and should not be construed as being limited to the descriptions set forth herein. Accordingly, the embodiments are merely described below, by referring to the drawings, to explain aspects of the present disclosure. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.

While the present disclosure is capable of various modifications and alternative forms, the embodiments of the present disclosure are shown in the drawings and will be described in detail in the written description. Effects and characteristics of the present disclosure and methods of achieving the same will become apparent by referring to the embodiments described in detail below along with the drawings. However, it should be noted that the embodiments of the present disclosure may have different forms and should not be construed as being limited to the description set for the herein.

It will be understood that although the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

It will be further understood that the terms “comprises” or “comprising” used herein specify the presence of stated features or components, but do not preclude the presence or addition of one or more other features or components.

In this specification, when elements, such as a layer, a film, an area, a plate, etc. are referred to as being “on” another element, it may indicate not only a case where the element is “directly on” the other element, but also a case where yet another element is between the element and the other element.

In this specification, it will be understood that when an element, an area, or a layer is referred to as being connected to another element, area, or layer, it may indicate that the element may be directly or indirectly connected to the other element, area, or layer. It will be understood in this specification that when an element, an area, or a layer is referred to as being in contact with or being electrically connected to another element, area, or layer, it can be directly or indirectly in contact with or electrically connected to the other element, area, or layer.

In this specification, the x-axis, the y-axis and the z-axis may not be limited to three axes of a rectangular coordinate system and may be interpreted in a broader sense. For example, the x-axis, the y-axis, and the z-axis may be perpendicular to one another, or may represent different directions that are not perpendicular to one another.

In this specification, when a certain embodiment may be implemented differently, a specific process order may be performed differently from the described order. For example, two consecutively described processes may be performed substantially at the same time or performed in an order opposite to the described order.

In this specification, the expression “in a plan view” may denote that an object is viewed downwardly. That is, in this specification, the expression “in a plan view” may denote that “an object is viewed in a direction perpendicular to a substrate 100.”

Hereinafter, embodiments of the present disclosure will be described in detail by referring to the accompanying drawings. In descriptions with reference to the drawings, the same reference numerals are given to components that are the same or substantially the same and descriptions will not be repeated. For convenience of explanation, elements in the drawings may have exaggerated or reduced sizes. For example, sizes and thicknesses of the elements in the drawings are randomly indicated for convenience of explanation, and thus, the disclosure is not necessarily limited to the illustrations of the drawings.

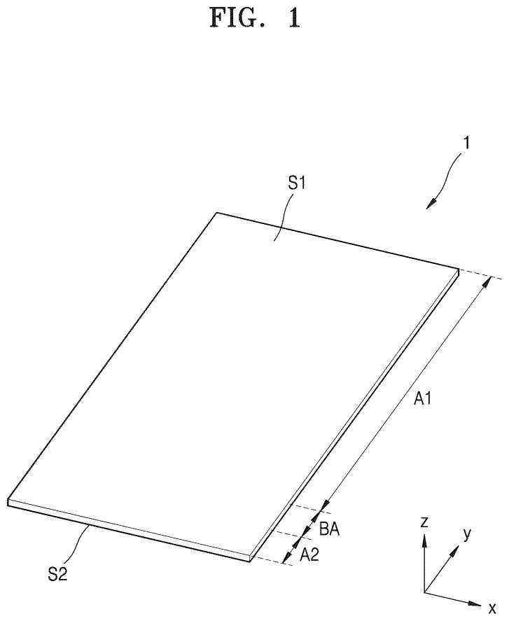

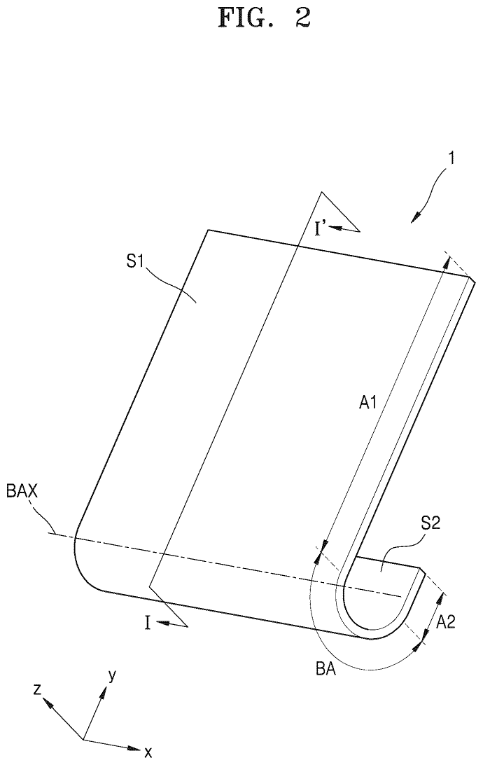

FIG. 1 is a schematic perspective view illustrating an unbent appearance of a display apparatus 1, according to an embodiment. FIG. 2 is a schematic perspective view illustrating a bent appearance of the display apparatus 1 according to an embodiment.

As illustrated in FIGS. 1 and 2, the display apparatus 1 may include a first area A1, a second area A2, and a bending area BA between the first area A1 and the second area A2. In detail, the display apparatus 1 may include the first area A1, the bending area BA outside the first area A1, and the second area A2 at the opposite side to the first area A1 with respect to the bending area BA.

The first area A1 may include a display area and a non-display area, and the second area A2 may include the non-display area. In the bending area BA, the display apparatus 1 may be bent as illustrated in FIG. 2, and thus, when viewed in a z-axis direction, at least a portion of the second area A2 may overlap the first area A1. In detail, the display apparatus 1 may be bent in the bending area BA, with respect to a bending axis BAX extending in a first direction (for example, a +x direction or a −x direction). Because the display apparatus 1 is bent in the bending area BA, a portion of the non-display area may not been seen when the display apparatus 1 is viewed in a −z direction. Thus, a visible area of the non-display area may be minimized.

The display apparatus 1 may include a first surface S1 and a second surface S2 at the opposite side to the first surface S1. The display apparatus 1 may display an image on the first surface S1. That is, the first surface S1 of the display apparatus 1 may include a display surface. In detail, the first surface S1 in the first area A1 of the display apparatus 1 may include the display surface. When the display apparatus 1 is bent in the bending area BA, the first surface S1 in the first area A1 may be arranged to face the second surface S2 in the second area A2.

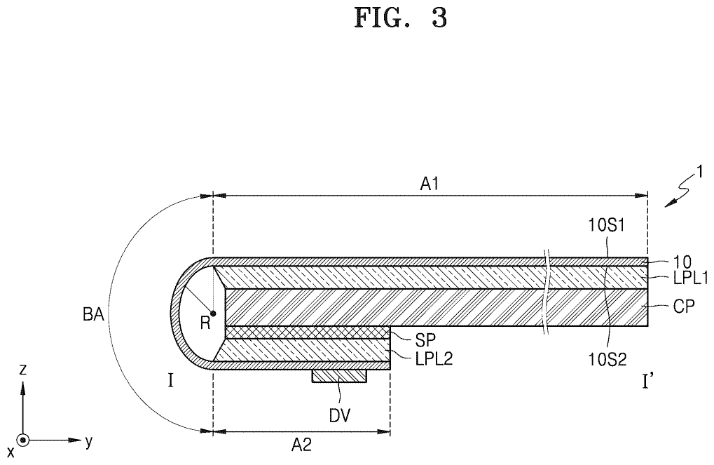

FIG. 3 is a schematic cross-sectional view of the display apparatus 1 of FIG. 2, taken along a line I-I′. As illustrated in FIG. 3, the display apparatus 1 may include a display panel 10, a first lower protective layer LPL1, a second lower protective layer LPL2, a lower cover panel CP, a spacer SP, and a driving portion DV.

The display panel 10 may display an image. To this end, the display panel 10 may include a plurality of display elements, and the plurality of display elements may emit light. Thus, the display panel 10 may display an image through the light emitted from the plurality of display elements. According to an embodiment, the display element may include an organic light-emitting diode including an organic emission layer. For example, the display element may include a light-emitting diode LED. A size of the light-emitting diode LED may be micro-scale or nano-scale. For example, the light-emitting diode LED may include a micro-light-emitting diode. For example, the light-emitting diode LED may include a nanorod-light-emitting diode. The nanorod-light-emitting diode may include GaN. According to an embodiment, a color conversion layer may be disposed on the nanorod-light-emitting diode. The color conversion layer may include quantum dots. The display element may include a quantum dot light-emitting diode including a quantum dot emission layer. The display element may include an inorganic light-emitting diode including an inorganic semiconductor. The elements included in the display panel 10 will be described in detail below.

As described above, the display apparatus 1 may include the first area A1, the second area A2, and the bending area BA. In addition, because the display apparatus 1 may include the display panel 10, it may be described that the display panel 10 may include the first area A1, the second area A2, and the bending area BA described above. Hereinafter, for convenience, it is described that the display panel 10 may have the first area A1, the second area A2, and the bending area BA.

The display panel 10 may include a first panel surface 10S1 and a second panel surface 10S2. The first panel surface 10S1 may correspond to the first surface S1 of the display apparatus 1, and the second panel surface 10S2 may correspond to the second surface S2 of the display apparatus 1. That is, the first panel surface 10S1 of the display panel 10 may be toward the same direction (for example, a +z direction) as the first surface S1 of the display apparatus 1, and the second panel surface 10S2 of the display panel 10 may be toward the same direction (for example, a −z direction) as the second surface S2 of the display apparatus 1. In other words, the display panel 10 may include the first panel surface 10S1 and the second panel surface 10S2 positioned at the opposite side to the first panel surface 10S1.

Lower protective layers may be disposed on the second panel surface 10S2 of the display panel 10. In detail, the first lower protective layer LPL1 may be disposed on the second panel surface 10S2 in the first area A1 of the display panel 10, and the second lower protective layer LPL2 may be disposed on the second panel surface 10S2 in the second area A2 of the display panel 10. In other words, as the display panel 10 may be bent in the bending area BA, the second panel surface 10S2 in the first area A1 and the second panel surface 10S2 in the second area A2 may be arranged to face each other. Thus, the first lower protective layer LPL1 may be disposed on the second panel surface 10S2 in the first area A1 of the display panel 10, in the-z direction, and the second lower protective layer LPL2 may be disposed on the second panel surface 10S2 in the second area A2 of the display panel 10, in the +z direction. The first lower protective layer LPL1 and the second lower protective layer LPL2 may be spaced apart from each other with the bending area BA therebetween. That is, a lower protective layer may not be disposed on the second panel surface 10S2 in the bending area BA, and thus, the display panel 10 may be easily bent.

The first lower protective layer LPL1 and the second lower protective layer LPL2 may protect the display panel 10 from the outside. For example, the first lower protective layer LPL1 and the second lower protective layer LPL2 may absorb external physical shocks, and each of the first lower protective layer LPL1 and the second lower protective layer LPL2 may prevent from the penetration of impurities, moisture, etc. into the display panel 10. According to an embodiment, the first lower protective layer LPL1 and the second lower protective layer LPL2 may include an organic insulating material such as polyethyleneterephthalate, polyimide, urethane acrylate, etc.

According to an embodiment, the first lower protective layer LPL1 and the second lower protective layer LPL2 may further include a material for blocking ultraviolet (UV) rays. For example, the first lower protective layer LPL1 and the second lower protective layer LPL2 may include a base resin, a UV absorbent, and an inorganic particle. The UV absorbent and the inorganic particle may be distributed in the base resin. For example, the base resin may include an acrylate-based resin, and may include, for example, urethane acrylate. However, the disclosure is not limited thereto. Base resins which are optically transparent, and which accommodate a UV absorbent and an inorganic particle distributed therein may be used for the first lower protective layer LPL1 and the second lower protective layer LPL2. For example, the UV absorbent may include at least one of a benzotriazol-based compound, a benzophenone-based compound, a salicylic acid-based compound, a salicylate-based compound, a cyanoacrylate-based compound, a cinnamate-based compound, an oxanilide-based compound, a polystyrene-based compound, an azomethine-based compound, and a triazine-based compound.

Although not shown, an adhesive member may be disposed between the display panel 10 and the first lower protective layer LPL1 and between the display panel 10 and the second lower protective layer LPL2. Each of the first lower protective layer LPL1 and the second lower protective layer LPL2 may be attached to the second panel surface 10S2 of the display panel 10 by using the adhesive member. The adhesive member may not be limited to particular types and any adhesive material known in the art may be used as the adhesive member. For example, the adhesive member may include an optically transparent adhesive (OCA) or a pressure-sensitive adhesive (PSA).

The lower cover panel CP may be disposed below the first lower protective layer LPL1. In detail, the lower cover panel CP may be disposed on a lower surface of the first lower protective layer LPL1. The lower cover panel CP may include at least one of a light-blocking layer, a cushion layer, and a heat-radiation layer.

The light-blocking layer may absorb light incident from the outside. For example, the light-blocking layer may include a black pigment or a black dye for absorbing external light. However, the disclosure is not limited thereto, and the light-blocking layer may include various materials capable of absorbing external light. The light-blocking layer may block the transmission of light, thereby preventing the elements disposed below the light-blocking layer from being seen from an upper surface of the display panel 10.

The cushion layer may absorb external shocks, thereby preventing or minimizing damage to the display panel 10. The cushion layer may include an elastic material. For example, the cushion layer may include foam formed of a polymer resin, such as polyurethane, polyethylene, polycarbonate, polypropylene, polyolefin, etc. For example, the cushion layer may include an elastic material, such as rubber, a foamed urethane-based material or an acryl-based material, etc., molded into sponges with elasticity. However, the materials described above are only examples. The cushion layer may include a material having excellent compression stress, and high impact and high vibration resistance.

The heat-radiation layer may dissipate heat generated from the display panel 10 efficiently to the outside. For example, the heat-radiation layer may include a metal, such as copper, nickel, ferrite, silver, or the like, that has excellent thermal conductivity and is capable of shielding an electromagnetic wave. For example, the heat-radiation layer may include graphite, a carbon nanotube, or the like.

According to an embodiment, the light-blocking layer of the lower cover panel CP may be disposed on the lower surface of the first lower protective layer LPL1. The cushion layer may be disposed on a lower surface of the light-blocking layer and the heat-radiation layer may be disposed on a lower surface of the cushion layer. However, the disclosure is not limited thereto. Relative positions of the light-blocking layer, the cushion layer, and the heat-radiation layer included in the lower cover panel CP may be variously changed.

The spacer SP may be disposed below the lower cover panel CP. In detail, the spacer SP may be disposed on a lower surface of the lower cover panel CP. As described above, when the bending area BA of the display panel 10 is bent, the second panel surface 10S2 in the first area A1 and the second panel surface 102S in the second area A2 may face each other. When the bending area BA of the display panel 10 is bent, the spacer SP may be disposed between the second panel surface 10S2 in the first area A1 and the second panel surface 10S2 in the second area A2. The spacer SP may support the display panel 10 when the bending area BA is bent.

Although not shown, an adhesive member may be disposed between the spacer SP and the lower cover panel CP and between the spacer SP and the second lower protective layer LPL2. The spacer SP may be attached to the lower cover panel CP and the second lower protective layer LPL2 by the adhesive member. The adhesive member may not be limited to particular types and any adhesive material known in the art may be used as the adhesive member. For example, the adhesive member may include an OCA or a PSA.

The driving portion DV may be disposed on the first panel surface 10S1 of the display panel 10. In detail, the driving portion DV may be disposed on the first panel surface 10S1 in the second area A2 of the display panel 10. The driving portion DV may receive control signals and power voltages and may generate and output signals and voltages for driving the display panel 10. The driving portion DV may include an integrated circuit (IC).

As the bending area BA is bent, the bending area BA may have a radius of curvature. For example, in a cross-sectional view, the bending area BA may include a curve having a certain radius of curvature. Here, the expression “in a cross-sectional view” may denote “in a cross-sectional view in an extension direction of the bending axis BAX, which is a virtual axis with respect to which the bending area BA is bent, or “in a virtual plan view perpendicular to the bending axis BAX, which is the virtual axis with respect to which the bending area BA is bent.” For example, FIG. 3 illustrates a cross-sectional view of the bending area BA and shows the bending area BA in the extension direction (that is, a −x direction of FIG. 2) of the bending axis BAX (see FIG. 2).

Also, here, the “curve” may include not only an arc, but also a portion of an oval or an amorphous arc. When the curve is an arc, the radius of curvature may be determined by a radius of the arc. When the curve includes a portion of an oval or an amorphous arc, the radius of curvature may be defined by a radius of an arc, when at least a portion of the curve is approximated as the arc. Hereinafter, for convenience of explanation, a case in which the curve includes an arc is described.

In detail, the second panel surface 10S2 of the bending area BA may have a radius of curvature R. The radius of curvature R of the second panel surface 10S2 of the bending area BA may be in a range of about 0.2 mm to about 0.4 mm. When the radius of curvature R of the second panel surface 10S2 of the bending area BA is less than 0.2 mm, the impact resistance of the bending area BA may deteriorate, and the bending area BA may be susceptible to external shocks. When the radius of curvature R of the second panel surface 10S2 of the bending area BA is greater than 0.4 mm, the non-display area of the display apparatus 1 may be excessively increased.

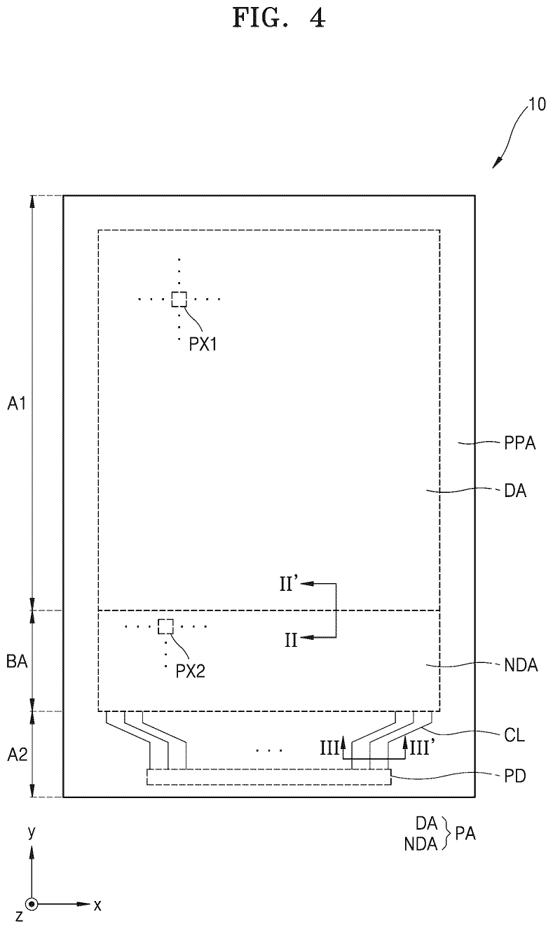

FIG. 4 is a schematic plan view illustrating an unbent appearance of the display panel 10 included in the display apparatus 1, according to an embodiment. As illustrated in FIG. 4, the display panel 10 may include a pixel area PA and a peripheral area PPA outside the pixel area PA. The pixel area PA may include the display area DA and the non-display area NDA.

A pixel may be arranged in the pixel area PA. The pixel may include a display element and a pixel circuit electrically connected thereto. The pixel may be provided in a plural number. The plurality of pixels may include a first pixel PX1 and a second pixel PX2. The first pixel PX1 may be provided in a plural number, and the second pixel PX2 may also be provided in a plural number. In detail, the first pixel PX1 may be arranged in the display area DA, and the second pixel PX may be arranged in the non-display area NDA. In other words, the display panel 10 may include a plurality of first pixels PX1 arranged in the display area DA and the display panel 10 may include a plurality of second pixels PX2 arranged in the non-display area NDA.

The display area DA may be an area which provides an image and may have a polygonal shape including a quadrangular shape, as illustrated in FIG. 4. For example, the display area DA may have a rectangular shape having a horizontal length that is less than a vertical length, a rectangular shape having a horizontal length that is greater than a vertical length, or a square shape. The display area DA may have various shapes other than the rectangular shape, for example, an oval shape or a circular shape. The first pixel PX1 of the display area DA may emit light of a certain color, and the display panel 10 may provide an image by using the light emitted from the first pixel PX1. For example, the first pixel PX1 may emit red, green, or blue light.

The non-display area NDA may be an area which does not provide an image, as illustrated in FIG. 4, and may be in contact with a side of the display area DA. In detail, the non-display area NDA may extend along a side of the display area DA. While the second pixel PX2 of the non-display area NDA may have the same or substantially the same structure as the first pixel PX1 of the display area DA, the second pixel PX may not emit light. That is, the second pixel PX2 disposed in the non-display area NDA may be a dummy pixel.

The display area DA may be arranged in the first area A1, and the non-display area NDA may be arranged in the bending area BA. That is, the display panel 10 may include the first pixel PX1 arranged in the first area A1 and the second pixel PX2 arranged in the bending area BA.

The peripheral area PPA may be an area which does not include pixels and may be an area which does not provide an image. As illustrated in FIG. 4, the peripheral area PPA may entirely surround the pixel area PA. A driver, etc. which provides an electrical signal or supplies a power to the pixels may be arranged in the peripheral area PPA.

As illustrated in FIG. 4, a pad portion PD and a connection line CL may be arranged in the peripheral area PPA. In detail, the pad portion PD may be arranged at an end of the display panel 10 to be adjacent to one side of the pixel area PA. For example, the pad portion PD may be arranged at an end of the display panel 10 which is adjacent to one side of the non-display area NDA. In other words, the non-display area NDA may be arranged between the display area DA and the pad portion PD. The connection line CL may be arranged between the pad portion PD and the pixel area PA. The connection line CL may be provided in a plural number.

A portion of the peripheral area PPA may be arranged in the first area A1, another portion of the peripheral area PPA may be arranged in the bending area BA, and yet another portion of the peripheral area PPA may be arranged in the second area A2. The pad portion PD and the connection line CL may be arranged in the peripheral area PPA in the second area A2. That is, the display panel 10 may include the pad portion PD and the connection line CL arranged in the second area A2.

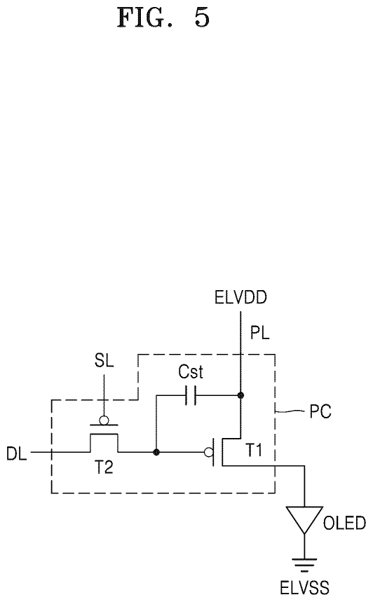

The pad portion PD may include a plurality of pads (not shown). The driving portion DV may be electrically connected to the plurality of pads of the pad portion PD. The pads may be spaced apart from each other, and the pads may be electrically connected to the plurality of connection lines CL, respectively. In other words, the connection lines CL may be electrically connected to the pad portion PD. The connection lines CL may electrically connect signal lines arranged in the pixel area PA, for example, data lines DL (see FIG. 5) or scan lines SL (see FIG. 5), to the pads. In other words, the connection lines CL may be electrically connected to the first pixel PX1 and the second pixel PX2 of the pixel area PA. That is, the connection lines CL may electrically connect the first pixel PX1 and the second pixel PX2 to the pad portion PD. Accordingly, the driving portion DV may be electrically connected, through the connection lines CL connected to the pad portion PD, to the data line DL arranged in the pixel area PA to provide a certain signal to the first pixel PX1 and the second pixel PX2.

FIG. 5 is an equivalent circuit diagram of a pixel of the display panel 10 of FIG. 4. As illustrated in FIG. 5, the pixel may include a display element and a pixel circuit PC electrically connected thereto. FIG. 5 illustrates an organic light-emitting diode OLED as the display element.

The pixel circuit PC may include a first transistor T1, a second transistor T2, and a storage capacitor Cst. The second transistor T2, which is a switching transistor, may be connected to the scan line SL and the data line DL and may be turned on in response to a switching signal that is input from the scan line SL and transmit a data signal that is input from the data line DL to the first transistor T1. The storage capacitor Cst may have an end electrically connected to the second transistor T2 and the other end electrically connected to a driving voltage line PL and may store a voltage corresponding to a difference between a voltage received from the second transistor T2 and a driving power voltage ELVDD supplied through the driving voltage line PL.

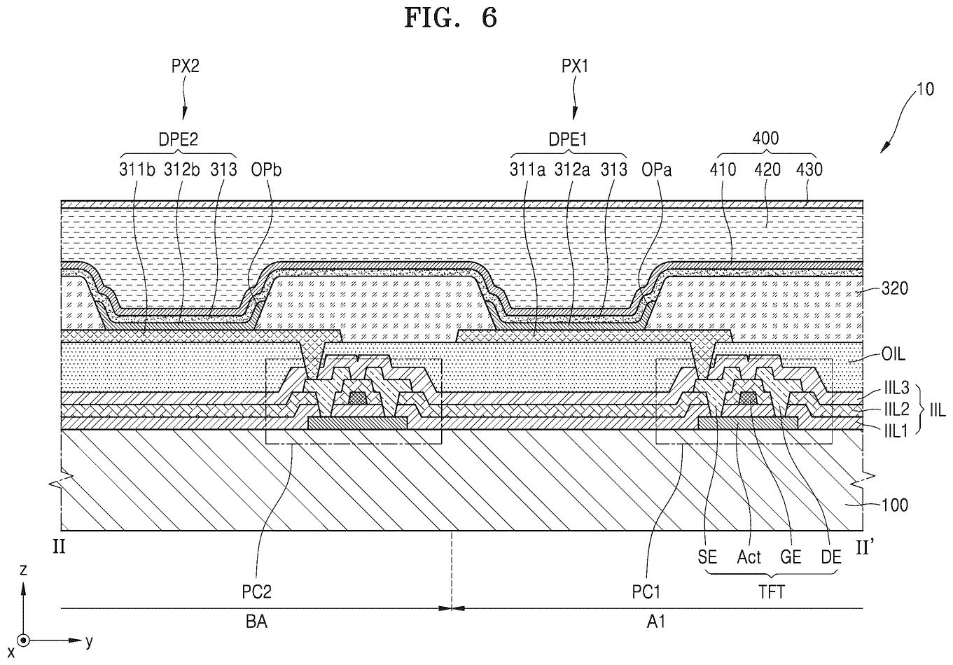

The first transistor T1, which is a driving transistor, may be connected to the driving voltage line PL and the storage capacitor Cst and may control a magnitude of a driving current flowing from the driving voltage line PL to the organic light-emitting diode OLED in response to the voltage stored in the storage capacitor Cst. The organic light-emitting diode OLED may emit light having a certain brightness according to the driving current. An opposite electrode 313 (see FIG. 6) of the organic light-emitting diode OLED may receive an electrode power voltage ELVSS.

FIG. 5 illustrates that the pixel circuit PC may include two transistors and one capacitor. However, the disclosure is not limited thereto. For example, the number of transistors and the number of storage capacitors may be variously changed according to the design of the pixel circuit PC.

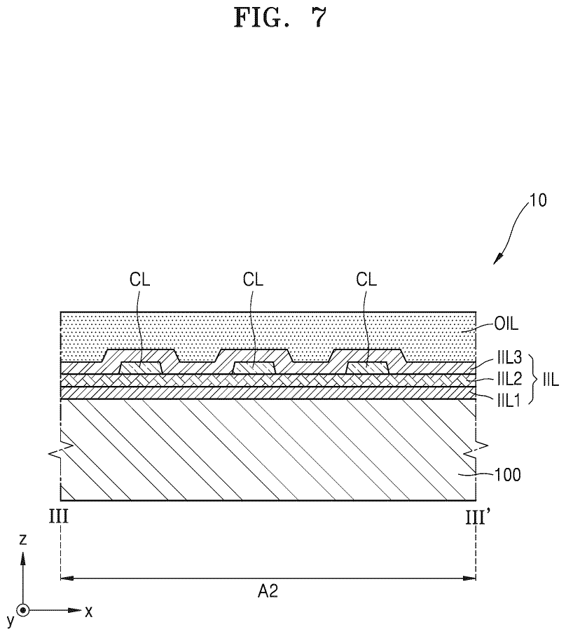

FIGS. 6 and 7 are schematic cross-sectional views of the display panel 10 included in the display apparatus 1 according to an embodiment. In detail, FIG. 6 is a schematic cross-sectional view of the display panel 10 of FIG. 4, taken along a line II-II′, and FIG. 7 is a schematic cross-sectional view of the display panel 10 of FIG. 4, taken along a line III-III′.

As illustrated in FIG. 6, the display panel 10 may include a substrate 100, an inorganic insulating layer IIL, a pixel circuit PC1 and PC2, an organic insulating layer OIL, a display element DPE1 and DPE2, a pixel-defining layer 320, and an encapsulation layer 400. The display panel 10 may include the substrate 100, and thus, the substrate 100 may have the pixel area PA and the peripheral area PPA, as described above.

The substrate 100 may include glass, metal, or polymer resins. The substrate 100 may be flexible or bendable. According to an embodiment of the present disclosure, the substrate 100 may include polymer resins, such as polyethersulfone, polyacrylate, polyetherimide, polyethylenenaphthalate, polyethyleneterephthalate, polyphenylenesulfide, polyarylate, polyimide, polycarbonate, or cellulose acetate propionate. However, the substrate 100 may be variously modified. For example, the substrate 100 may have a layered structure including the polymer resins described above and a barrier layer between the two layers. The barrier layer may include an inorganic material, such as SiOₓ, SiNₓ, SiOₓN_{y}, etc.

The inorganic insulating layer IIL may be disposed on the substrate 100, and the organic insulating layer OIL may be disposed on the inorganic insulating layer IIL. The inorganic insulating layer IIL may include a gate insulating layer IIL1, a first interlayer insulating layer IIL2, and a second interlayer insulating layer IIL3.

The pixel circuit may be provided in a plural number. The plurality of pixel circuits may include a first pixel circuit PC1 and a second pixel circuit PC2. In detail, the first pixel circuit PC1 may be arranged in the first area A1, and the second pixel circuit PC2 may be arranged in the bending area BA. For example, the first pixel circuit PC1 may be arranged in the display area DA, and the second pixel circuit PC2 may be arranged in the non-display area NDA. That is, the first pixel circuit PC1 may be a pixel circuit of the first pixel PX1, and the second pixel circuit PC2 may be a pixel circuit of the second pixel PX2. The first pixel circuit PC1 and the second pixel circuit PC2 may have the same structure as each other. Thus, the first pixel circuit PC1 is to be mainly described.

As illustrated in FIG. 6, the first pixel circuit PC1 may include a transistor TFT, and the transistor TFT may include a semiconductor layer Act, a gate electrode GE, a source electrode SE, and a drain electrode DE. As described above with reference to FIG. 5, the pixel circuit may include the first transistor T1, the second transistor T2, and the storage capacitor Cst. However, for convenience of illustration, FIG. 6 illustrates one transistor TFT, which may correspond to the first transistor T1 (see FIG. 5) described above.

The semiconductor layer Act may be disposed on the substrate 100. The semiconductor layer Act may include polysilicon, amorphous silicon, an oxide semiconductor, an organic semiconductor, or the like. According to an embodiment, the semiconductor layer Act may include a channel area, and a source area and a drain area arranged at both sides of the channel area, respectively.

The gate insulating layer IIL1 may be disposed on the semiconductor layer Act and the substrate 100. The gate insulating layer IIL1 may include an inorganic insulating material, such as SiOₓ, SiNₓ, SiOₓN_{y}, Al₂O₃, TiO₂, Ta₂O₅, HfO₂, or ZnOₓ. ZnOₓ may include ZnO or ZnO₂.

The gate electrode GE may be disposed on the gate insulating layer IIL1. That is, the gate insulating layer IIL1 may be disposed between the semiconductor layer Act and the gate electrode GE, and thus, the semiconductor layer Act and the gate electrode GE may be insulated from each other. The gate electrode GE may overlap the channel area of the semiconductor layer Act. The gate electrode GE may include a metal having a low-resistance. According to an embodiment, the gate electrode GE may include a conductive material including Mo, Al, Cu, Ti, etc. and may have a single-layered or layered structure including the conductive materials described above.

The first interlayer insulating layer IIL2 may be disposed on the gate electrode GE and the gate insulating layer IIL1. The first interlayer insulating layer IIL2 may include an inorganic insulating material, such as SiOₓ, SiNₓ, SiOₓN_{y}, Al₂O₃, TiO₂, TA₂O₅, HfO₂, or ZnOₓ.

The source electrode SE and the drain electrode DE may be disposed on the first interlayer insulating layer IIL2. Each of the source electrode SE and the drain electrode DE may be connected to the semiconductor layer Act through a contact hole formed in the gate insulating layer IIL1 and the first interlayer insulating layer IIL2. At least one of the source electrode SE and the drain electrode DE may include a conductive material including Mo, Al, Cu, or Ti and may have a single-layered or layered structure including the conductive materials described above. According to an embodiment, at least one of the source electrode SE and the drain electrode DE may have a layered structure of Ti/Al/Ti.

The second interlayer insulating layer IIL3 may be disposed on the source electrode SE, the drain electrode DE, and the first interlayer insulating layer IIL2. The second interlayer insulating layer IIL3 may include an inorganic insulating material, such as SiOₓ, SiNₓ, SiOₓN_{y}, Al₂O₃, TiO₂, Ta₂O₅, HfO₂, or ZnOₓ.

The organic insulating layer OIL may be disposed on the second interlayer insulating layer IIL3. An upper surface of the organic insulating layer OIL may be flat. The organic insulating layer OIL may include an organic material, such as acryl, benzocyclobutene (BCB), or hexamethyldisiloxane (HMDSO). While FIG. 6 illustrates that the organic insulating layer OIL includes a single layer, the organic insulating layer OIL may include a plurality of layers. That is, the organic insulating layer OIL may be modified in various ways.

The display element may be disposed on the organic insulating layer OIL. The display element may be provided in a plural number. The plurality of display elements may include a first display element DPE1 and a second display element DPE2. In detail, the first display element DPE1 may be arranged in the first area A1, and the second display element DPE2 may be arranged in the bending area BA. For example, the first display element DPE1 may be arranged in the display area DA, and the second display element DPE2 may be arranged in the non-display area NDA. That is, the first display element DPE1 may be a display element of the first pixel PX1, and the second display element DPE2 may be a display element of the second pixel PX2.

The display element may include, for example, an organic light-emitting diode including a pixel electrode, an opposite electrode, and an emission layer between the pixel electrode and the opposite electrode. The first display element DPE1 may include a first pixel electrode 311a, a first emission layer 312a, and the opposite electrode 313. The second display element DPE2 may include a second pixel electrode 311b, a second emission layer 312b, and the opposite electrode 313. The display element may be electrically connected to the pixel circuit. That the display element may be electrically connected to the pixel circuit may denote that the pixel electrode included in the display element may be electrically connected to the source electrode or the drain electrode of the pixel circuit. For example, the first pixel electrode 311a of the first display element DPE1 may be electrically connected to the source electrode SE or the drain electrode DE of the first pixel circuit PC1, and the second pixel electrode 311b of the second display element DPE2 may be electrically connected to the source electrode SE or the drain electrode DE of the second pixel circuit PC2.

In detail, the first pixel electrode 311a and the second pixel electrode 311b may be disposed on the organic insulating layer OIL. The first pixel electrode 311a may be disposed in the first area A1, and the second pixel electrode 311b may be disposed in the bending area BA. The first pixel electrode 311a and the second pixel electrode 311b may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). The first pixel electrode 311a and the second pixel electrode 311b may include a reflective layer including Ag, Mg, Al, Pt, Pd, Au, Ni, Nd, Ir, Cr, or a compound thereof. The first pixel electrode 311a and the second pixel electrode 311b may further include a layer including ITO, IZO, ZnO, or In₂O₃ above or below the reflective layer described above.

The pixel-defining layer 320 may be disposed on the organic insulating layer OIL. The pixel-defining layer 320 may cover edges of the pixel electrodes. That is, the pixel-defining layer 320 may have an opening corresponding to each pixel and thus may define an emission area of each pixel. In detail, a first opening OPa defined in the pixel-defining layer 320 may expose a central portion of the first pixel electrode 311a, and by the first opening OPa, an emission area through which light is emitted from the first display element DPE1 may be defined. Similarly, the second opening OPb defined in the pixel-defining layer 320 may expose a central portion of the second pixel electrode 311b. The pixel-defining layer 320 may include an organic insulating material or an inorganic insulating material. According to an embodiment, the pixel-defining layer 320 may include a light-blocking material.

A first emission layer 312a may be disposed on the first pixel electrode 311a. A second emission layer 312b may be disposed on the second pixel electrode 311b. The first emission layer 312a and the second emission layer 312b may include a low molecular-weight material or a high molecular-weight material, and may emit red, green, or blue light. However, the disclosure is not limited thereto. The first emission layer 312a and the second emission layer 312b may include an organic light-emitting material for emitting light.

The opposite electrode 313 may be disposed on the first emission layer 312a and the second emission layer 312b. That is, the opposite electrode 313 may be integrally formed throughout the plurality of display elements and may correspond to the plurality of pixel electrodes, for example, the first pixel electrode 311a and the second pixel electrode 311b. The opposite electrode 313 may be formed to entirely cover the pixel area, and thus, may be disposed on the pixel-defining layer 320. Also, the opposite electrode 313 may include a conductive material having a low work function. For example, the opposite electrode 313 may include a (semi-) transparent layer including Ag, Mg, Al, Pt, Pd, Au, Ni, Nd, Ir, Cr, Li, Ca, or an alloy thereof. The opposite electrode 313 may further include a layer, such as ITO, IZO, ZnO, or In₂O₃, on the (semi-) transparent layer including the material described above.

The first pixel PX1 may include the first display element DPE1 and the first pixel circuit PC1, and the second pixel PX2 may include the second display element DPE2 and the second pixel circuit PC2. As described above, the first display element DPE1 may have the same or substantially the same structure as the second display element DPE2, and the first pixel circuit PC1 may have the same or substantially the same structure as the second pixel circuit PC2. Accordingly, the first pixel PX1 arranged in the first area A1 and the second pixel PX2 arranged in the bending area BA may have the same or substantially the same structure as each other. However, the first pixel PX1 arranged in the first area A1 may emit light while a user is using the display apparatus 1, and the second pixel PX2 arranged in the bending area BA may not emit light while the user is using the display apparatus 1.

The display elements may be easily damaged by external moisture or oxygen, and thus, the encapsulation layer 400 may be provided to cover and protect the display elements. As illustrated in FIG. 6, the encapsulation layer 400 may include a first inorganic encapsulation layer 410, an organic encapsulation layer 420, and a second inorganic encapsulation layer 430.

The first inorganic encapsulation layer 410 may cover the opposite electrode 313 and may include SiOₓ, SiNₓ, or SiOₓNY. Although it is not shown in FIG. 6, other layers, such as a capping layer, etc., may be disposed between the first inorganic encapsulation layer 410 and the opposite electrode 313. The first inorganic encapsulation layer 410 may be formed along the structure therebelow. Thus, an upper surface of the first inorganic encapsulation layer 410 may not be flat, as illustrated in FIG. 6. The organic encapsulation layer 420 may cover the first inorganic encapsulation layer 410. However, unlike the first inorganic encapsulation layer 410, an upper surface of the organic encapsulation layer 420 may be flat. The organic encapsulation layer 420 may include one or more materials selected from the group consisting of polyethyleneterephthalate, polyethylenenaphthalate, polycarbonate, polyimide, polyethylenesulfonate, polyoxymethylene, polyarylate, and hexamethyldisiloxane. The second inorganic encapsulation layer 430 may cover the organic encapsulation layer 420 and may include SiOₓ, SiNₓ, or SiOₓNY.

Because the encapsulation layer 400 may include the first inorganic encapsulation layer 410, the organic encapsulation layer 420, and the second inorganic encapsulation layer 430, even when cracks occur in the encapsulation layer 400, the cracks may be prevented from propagating between the first inorganic encapsulation layer 410 and the organic encapsulation layer 420 or between the organic encapsulation layer 420 and the second inorganic encapsulation layer 430. Thus, formation of a path, through which external moisture or oxygen may penetrate into the display panel 10, may be prevented or minimized.

As illustrated in FIG. 7, the connection line CL may be arranged in the second area A2. The connection line CL may be provided in a plural number, and the plurality of connection lines CL may be arranged to be apart from each other in a first direction (for example, a +x direction or a −x direction).

The inorganic insulating layer IIL and the organic insulating layer OIL described above with reference to FIG. 6 may be formed on the entire surface of the substrate 100. Accordingly, the inorganic insulating layer IIL and the organic insulating layer OIL may also be arranged in the second area A2. The connection line CL may be disposed between the first interlayer insulating layer IIL2 and the second interlayer insulating layer IIL3 of the inorganic insulating layer IIL. FIG. 7 illustrates that only the inorganic insulating layer IIL and the organic insulating layer OIL are disposed on the connection line CL. However, the disclosure is not limited thereto. For example, the encapsulation layer 400 may be disposed on the connection line CL.

The connection line CL may include the same material as at least one of the source electrode SE and the drain electrode DE. For example, the connection line CL may include a conductive material including Mo, Al, Cu, Ti, or the like and may have a single-layered or layered structure including the conductive materials described above. According to an embodiment, the connection line CL may have a layered structure of Ti/Al/Ti.

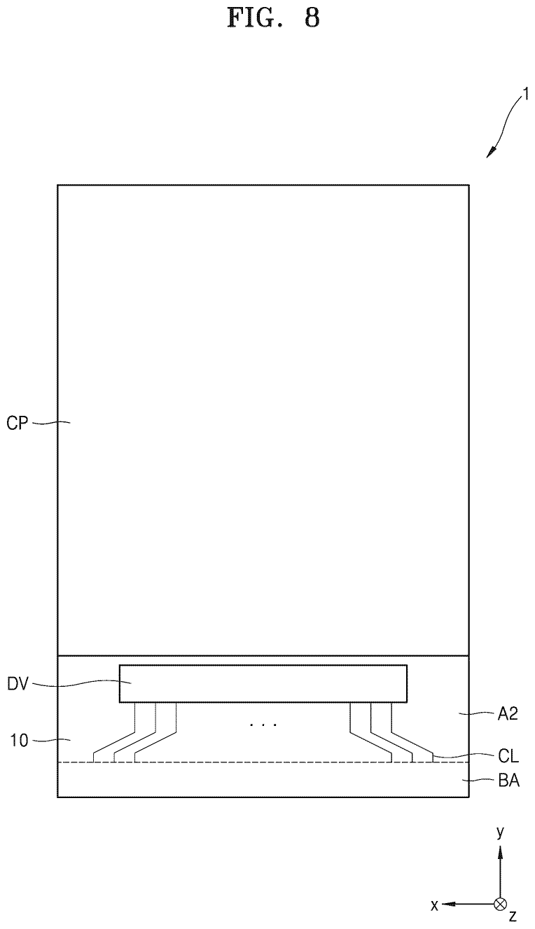

FIG. 8 is a schematic rear view of the display apparatus 1 according to an embodiment. In detail, FIG. 8 is the rear view of the display apparatus 1 of FIG. 2, in a +z direction. For convenience of explanation, FIG. 8 also illustrates the connection line CL. As described above, the connection line CL may be arranged in the second area A2. Thus, when the display apparatus 1 is bent, the connection line CL may not be visible from the front side of the display apparatus 1.

As the connection lines CL according to an embodiment of the present disclosure is disposed only in the second area A2, the visible area of the non-display area of the display apparatus 1 may be reduced.

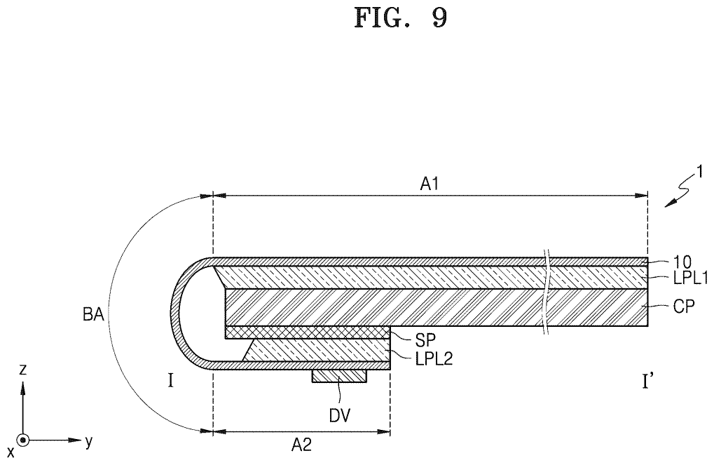

FIG. 3 illustrates that the second lower protective layer LPL2 may entirely cover a surface of the second area A2. However, the disclosure is not limited thereto. For example, as illustrated in FIG. 9, which is a schematic cross-sectional view of the display apparatus 1 according to an embodiment, an end of the second lower protective layer LPL2, which is adjacent to the bending area BA, may be arranged to be apart from the bending area BA. In other words, the second lower protective layer LPL2 may not be disposed on a surface (for example, the second panel surface 10S2) of a portion of the second area A2 adjacent to the bending area BA.

In general, compared with the first area A1 and the second area A2, the bending area BA may have lower impact resistance. Also, cracks may easily occur due to external shocks at a boundary between a portion of the display panel 10 where the second lower protective layer LPL2 is disposed and a portion of the display panel 10 where the second lower protective layer LPL2 is not disposed. Thus, when an end of the second lower protective layer LPL2 is in contact with the bending area BA (e.g., a portion of the bending area BA), the portion which contacts the end of the second lower protective layer LPL2 may be susceptible to external shocks. However, in the case of the display apparatus 1 according to an embodiment, the end of the second lower protective layer LPL2 does not contact the bending area BA and may be spaced apart from the bending area BA. Thus, the impact resistance of the display panel 10 may be increased.

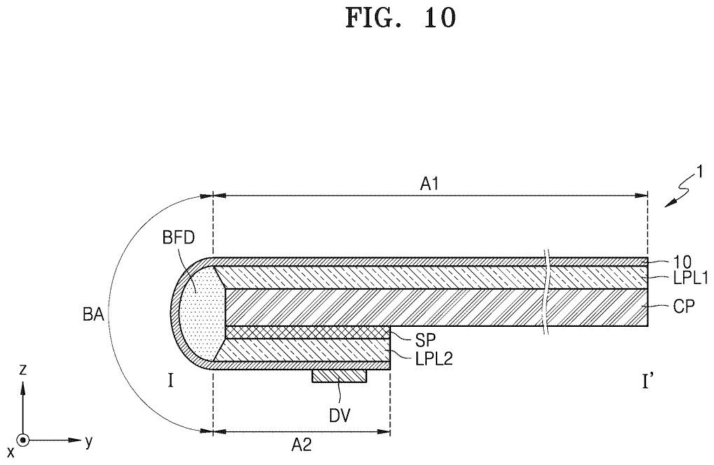

FIGS. 3 and 9 illustrate that a space defined by the bending area BA, the first lower protective layer LPL1, the lower cover panel CP, the spacer SP, and the second lower protective layer LPL2 or a space defined by the bending area BA, the first lower protective layer LPL1, the lower cover panel CP, the spacer SP, the second lower protective layer LPL2, and a portion of the second area A2 where the second lower protective layer LPL2 is spaced apart from the bending area BA may not be filled with other elements. However, the disclosure is not limited thereto. That is, as illustrated in FIG. 10, which is a schematic cross-sectional view of the display apparatus 1 according to an embodiment, the display apparatus 1 may include a filling member BFD.

The filling member BFD may fill the space defined by the bending area BA, the first lower protective layer LPL1, the lower cover panel CP, the spacer SP, and the second lower protective layer LPL2. In detail, as depicted in FIG. 10, the bending area BA, the first lower protective layer LPL1, the lower cover panel CP, the spacer SP, and the second lower protective layer LPL2 may define a space. The filling member BFD may fill the space. In other words, the filling member BFD may be arranged in the space defined by the bending area BA, the first lower protective layer LPL1, the lower cover panel CP, the spacer SP, and the second lower protective layer LPL2. That is, the filling member BFD may be disposed on the second panel surface 10S2 in the bending area BA.

The filling member BFD may include an elastic material. Accordingly, when an external force is applied to the bending area BA, the filling member BFD may absorb the external force, and thus, damage to the bending area BA may be prevented. For example, the filling member BFD may include at least one of an acryl-based resin, an epoxy-based resin, and a urethane-based resin. For example, the filling member BFD may include at least one of polyurethane and polyacrylate. However, the disclosure is not limited thereto, and a material having an elasticity and absorbing shocks when an external force is applied to the bending area BA may be used for the filling member BFD.

The filling member BFD may also fill the space, as illustrated in FIG. 9, defined by the bending area BA, the first lower protective layer LPL1, the lower cover panel CP, the spacer SP, the second lower protective layer LPL2, and a portion of the second area A2 where the second lower protective layer LPL2 is spaced apart from the bending area BA.

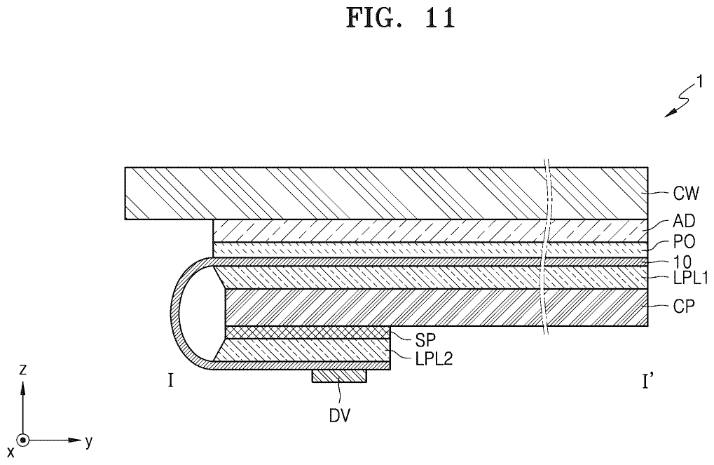

As illustrated in FIG. 11, which is a schematic cross-sectional view of the display apparatus 1 according to an embodiment, the display apparatus 1 may further include an optical functional layer PO, a cover window CW, and an adhesive layer AD.

The cover window CW may be disposed above the display panel 10. In detail, the cover window CW may be disposed in the first area A1 of the display panel 10. That is, the cover window CW may be disposed to cover the first panel surface 10S1 in the first area A1 of the display panel 10. The cover window CW may protect the first panel surface 10S1 in the first area A1 of the display panel 10.

The cover window CW may have a high transmittance to transmit the light emitted from the display panel 10 and a thin thickness to minimize the weight of the display apparatus 1. Also, the cover window CW may have the great rigidity and hardness to protect the display panel 10 from external shocks. The cover window CW may include a flexible window. The cover window CW may be easily bent by an external force to protect the display panel 10 without cracks, etc. The cover window CW may include glass or plastic. According to an embodiment, the cover window CW may include an ultra-thin glass (UTG) whose strength is enhanced by a chemical enhancement method or a thermal enhancement method. According to an embodiment, the cover window CW may include a polymer resin.

The optical functional layer PO may be disposed between the display panel 10 and the cover window CW. In detail, the optical functional layer PO may be disposed on the display panel 10. The optical functional layer PO may reduce the reflectivity of light (for example, external light) that is incident from the outside toward the display panel 10. Accordingly, the optical functional layer PO may improve the color purity of light emitted from the display panel 10. The optical functional layer PO may include a phase retarder and a polarization film including a polarizer. The phase retarder may include a λ/2 phase retarder or a λ/4 phase retarder.

The adhesive layer AD may be disposed between the optical functional layer PO and the cover window CW. In detail, the adhesive layer AD may be disposed on the optical functional layer PO. The cover window CW may be attached to the optical functional layer PO by the adhesive layer AD. The adhesive layer AD may include an adhesive member, such as an OCA or a PSA. Although not shown, the adhesive member may also be disposed between the display panel 10 and the optical functional layer PO. The optical functional layer PO may be attached to the first panel surface 10S1 of the display panel 10 by the adhesive member. The adhesive member may not be limited to particular types and any adhesive material known in the art may be used as the adhesive member. For example, the adhesive member may include an OCA or a PSA. Also, in an embodiment of the present disclosure, as the connection line CL may be disposed in the second area A2, a visible area of the non-display area may be reduced.

The display apparatus 1 is described above. However, the disclosure is not limited thereto. It shall be understood that a method of manufacturing the display apparatus 1 may also be included in the scope of the present disclosure. Hereinafter, the method of manufacturing the display apparatus 1 is described.

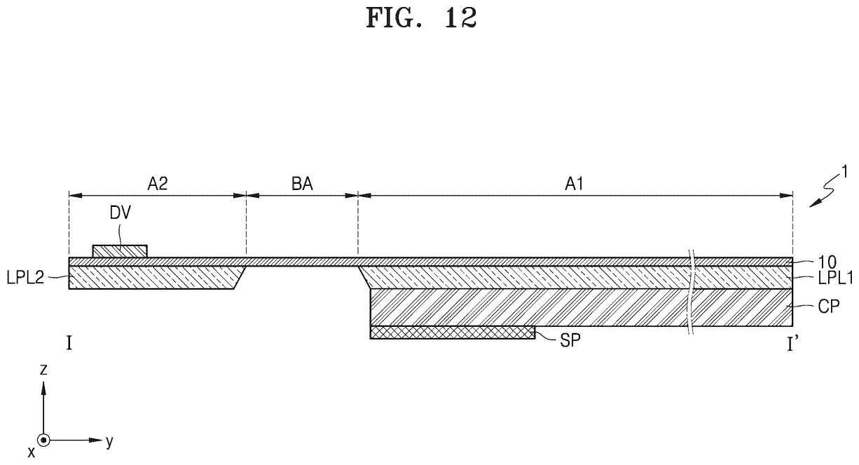

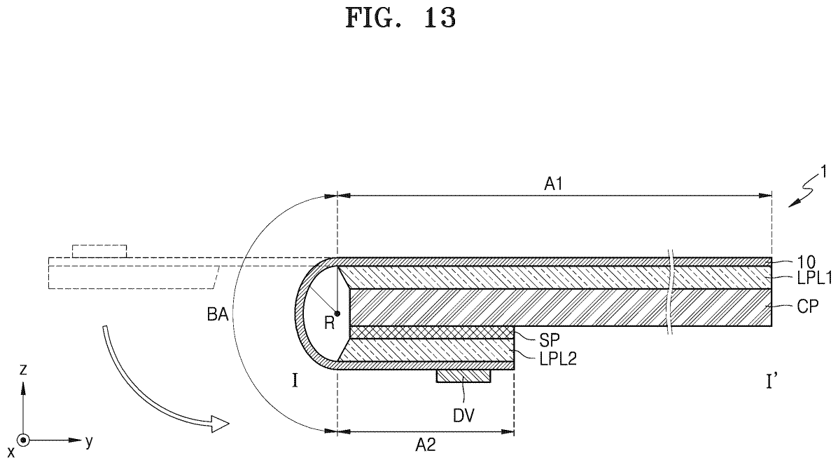

FIGS. 12 and 13 are schematic cross-sectional views illustrating a part of a process of manufacturing the display apparatus 1 of FIG. 3. In detail, FIGS. 12 and 13 are schematic cross-sectional views illustrating a process of bending the display apparatus 1 of FIG. 3. Referring to FIGS. 12 and 13, for convenience of explanation, the method of manufacturing the display apparatus will be described based on the display apparatus 1 depicted in FIG. 3. Hereinafter, when describing the method of manufacturing the display apparatus according to an embodiment, the same reference numerals as in FIGS. 1 to 8 may denote the same components as in FIGS. 1 to 8, and thus, the same descriptions are omitted.

As illustrated in FIG. 12, the display panel 10 may be prepared. As described above, the display panel 10 may include the first area A1, the second area A2, and the bending area BA. The bending area BA may be arranged between the first area A1 and the second area A2. In the first area A1, the first pixel PX1 may be arranged, and in the bending area BA, the second pixel PX2 may be arranged. In other words, the display panel 10 may include the first pixel PX1 disposed in the first area A1 and the second pixel PX2 disposed in the bending area BA.

In the second area A2, the pad portion PD and the connection line CL may be arranged. The connection line CL may electrically connect the first pixel PX1 and the second pixel PX2 to the pad portion PD. In other words, the display panel 10 may include the pad portion PD and the connection line CL disposed in the second area A2.

The display panel 10 may include the first panel surface 10S1 and the second panel surface 10S2 positioned at the opposite side to the first panel surface 10S1. According to an embodiment, the first lower protective layer LPL1 may be attached to the second panel surface 10S2 in the first area A1, and the second lower protective layer LPL2 may be attached to the second panel surface 10S2 in the second area A2. The lower cover panel CP may be attached below the first lower protective layer LPL1, and the spacer SP may be attached below the lower cover panel CP. An end of the second lower protective layer LPL2 may be in contact with the bending area BA. The driving portion DV may be attached to the first panel surface 10S1 of the display panel 10.

The first lower protective layer LPL1 and the second lower protective layer LPL2 may be attached onto the display panel 10 by an adhesive member. The lower cover panel CP may be attached to the first lower protective layer LPL1 by the adhesive member, and the spacer SP may be attached to the lower cover panel CP by the adhesive member. The adhesive member may not be limited to particular types and any adhesive material known in the art may be used as the adhesive member. For example, the adhesive member may include an OCA or a PSA.

As illustrated in FIG. 13, the display panel 10 may be bent. In detail, the display panel 10 may be bent in the bending area BA with respect to the bending axis BAX extending in a first direction (for example, a +x direction or a −x direction). The radius of curvature R of the bending area BA may be in a range of about 0.2 mm to about 0.4 mm. When the display panel 10 is bent, the second panel surface 10S2 in the first area A1 may face the second panel surface 10S2 in the second area A2. That is, the first lower protective layer LPL1 may be disposed on the second panel surface 10S2 in the first area A1 of the display panel 10, in the-z direction, and the second lower protective layer LPL2 may be disposed on the second panel surface 10S2 in the second area A2 of the display panel 10, in the +z direction.

Accordingly, the second lower protective layer LPL2 disposed on the second panel surface 10S2 in the second area A2 of the display panel 10 may be disposed below the spacer SP, and the second lower protective layer LPL2 may be attached to the spacer SP. That is, the second lower protective layer LPL2 may be attached to a lower surface of the spacer SP.

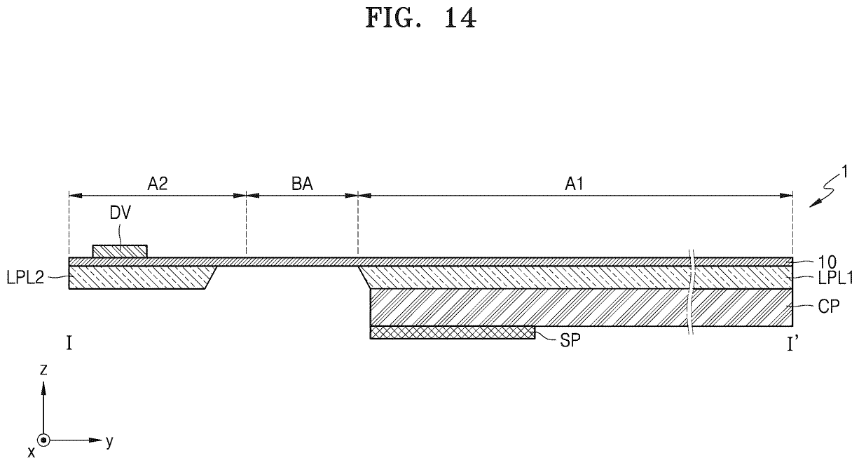

FIG. 14 is a schematic cross-sectional view illustrating a part of a process of manufacturing the display apparatus 1 of FIG. 9. In detail, FIG. 14 is the schematic cross-sectional view illustrating a process of preparing the display panel 10 of the display apparatus 1 of FIG. 9. A method of manufacturing the display apparatus according to the present embodiment may correspond to a modified embodiment of the method of manufacturing the display apparatus described above with reference to FIGS. 12 and 13. Thus, hereinafter, differences from the method of manufacturing the display apparatus described above with reference to FIGS. 12 and 13 are mainly described. In FIG. 14, the same reference numerals as in FIGS. 12 and 13 denote the same components as in FIGS. 12 and 13, and thus, their descriptions are not repeated.

According to the method of manufacturing the display apparatus according to the present embodiment, the display panel 10 may include the first area A1, the second area A2, and the bending area BA. The first pixel PX1 may be arranged in the first area A1, the second pixel PX2 may be arranged in the bending area BA, and the pad portion PD and the connection line CL may be arranged in the second area A2. The display panel 10 may include the first panel surface 10S1 and the second panel surface 10S2 positioned at the opposite side to the first panel surface 10S1. The first lower protective layer LPL1 may be attached to the second panel surface 10S2 in the first area A1 and the second lower protective layer LPL2 may be attached to the second panel surface 10S2 in the second area A2. The lower cover panel CP may be attached below the first lower protective layer LPL1, and the spacer SP may be attached below the lower cover panel CP.

According to an embodiment of the manufacturing method of the display apparatus, as depicted in FIG. 14, an end of the second lower protective layer LPL2 (e.g., the end being adjacent to the bending area BA) may be spaced apart from the bending area BA. Thus, the second lower protective layer LPL2 may not be disposed on the second panel surface 10S2 in a portion of the second area A2 adjacent to the bending area BA. Accordingly, even when the display panel 10 is bent, an end of the second lower protective layer LPL2 adjacent to the bending area BA may be spaced apart from the bending area BA. Thus, the impact resistance of the display panel 10 may be improved.

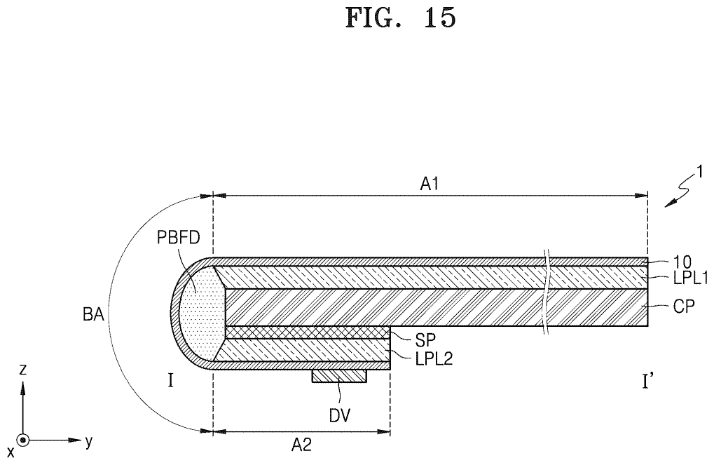

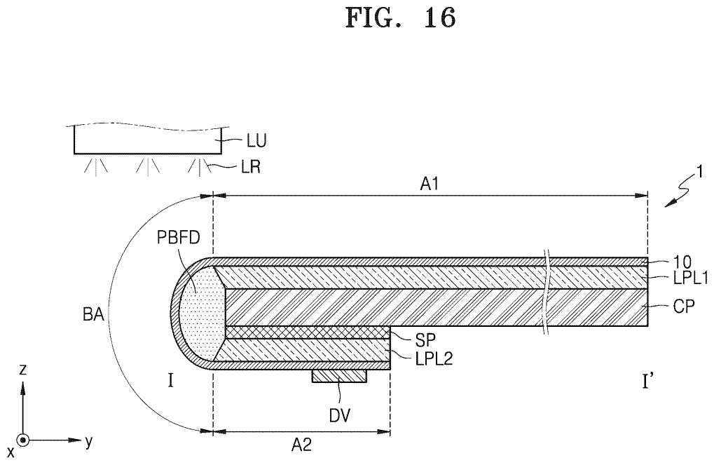

FIGS. 15 and 16 are schematic cross-sectional views illustrating a part of a process of manufacturing the display apparatus 1 of FIG. 10. In detail, FIGS. 15 and 16 are schematic cross-sectional views illustrating a process of forming the filling member BFD of the display apparatus 1 of FIG. 10. A method of manufacturing the display apparatus according to the present embodiment may correspond to a modified embodiment of the method of manufacturing the display apparatus described above with reference to FIGS. 12 and 13. Thus, hereinafter, differences from the method of manufacturing the display apparatus described above with reference to FIGS. 12 and 13 are mainly described. In FIGS. 15 and 16, the same reference numerals as in FIGS. 12 and 13 denote the same components as in FIGS. 12 and 13, and thus, their descriptions are not repeated.

Like the method of manufacturing the display apparatus described above with reference to FIGS. 12 and 13, according to the method of manufacturing the display apparatus according to the present embodiment, the display panel 10 may be prepared and the display panel 10 may be bent. The display panel 10 may include the first area A1, the second area A2, and the bending area BA. The first pixel PX1 may be arranged in the first area A1, the second pixel PX2 may be arranged in the bending area BA, and the pad portion PD and the connection line CL may be arranged in the second area A2. The display panel 10 may include the first panel surface 10S1 and the second panel surface 10S2 positioned at the opposite side to the first panel surface 10S1. The first lower protective layer LPL1 may be attached to the second panel surface 10S2 in the first area A1, and the second lower protective layer LPL2 may be attached to the second panel surface 10S2 in the second area A2. The lower cover panel CP may be attached below the first lower protective layer LPL1, and the spacer SP may be attached below the lower cover panel CP.

The display panel 10 according to an embodiment may include a space which is defined by the bending area BA, the first lower protective layer LPL1, the lower cover panel CP, the spacer SP, and the second lower protective layer LPL2, as depicted in FIG. 15. The space may be filled with a material for forming the filling member PBFD. The filling the space with a material for forming the filling member PBFD may follow a general method of manufacturing the display apparatus, and thus, its detailed description is omitted.

As illustrated in FIG. 16, UV rays may be irradiated to the material for forming the filling member PBFD. Thus, the filling member BFD may be formed. In detail, the UV rays LR having the light amount of about 100 mJ/cm² to about 1000 mJ/cm² emitted from an external light source LU may be irradiated to the material for forming the filling member PBFD to photopolymerize the material for forming the filling member PBFD. For the photopolymerization, the UV rays having the wavelength of about 300 nm to about 400 nm may be used. A source of the UV rays may include a light-emitting diode or metal halide. That is, by irradiating the UV rays to the material for forming the filling member PBFD, the material for forming the filling member PBFD may be photopolymerized.

The filling member BFD may include an elastic material. For example, the filling member BFD may include at least one of an acryl-based resin, an epoxy-based resin, and a urethane-based resin. For example, the filling member BFD may include at least one of polyurethane and polyacrylate. However, the disclosure is not limited thereto. A material which may be cured to form the filling member BFD may be used as the material for forming the filling member PBFD. Accordingly, when an external force is applied to the bending area BA, the filling member BFD may absorb shocks to prevent damage to the bending area BA.

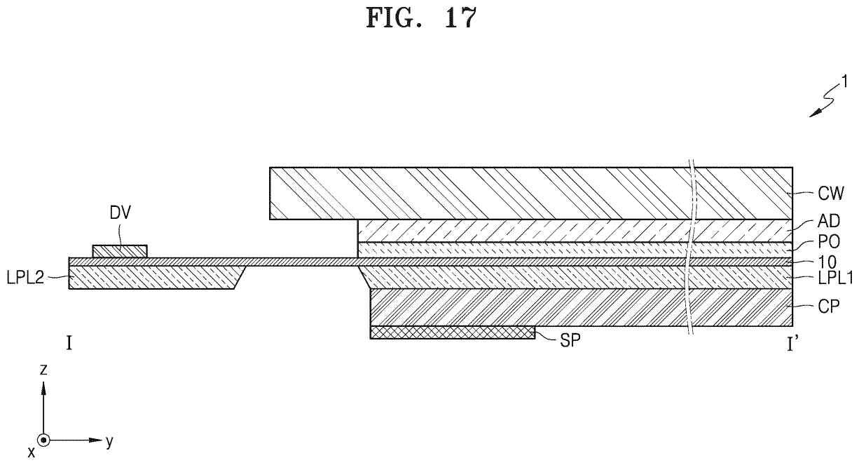

FIG. 17 is a schematic cross-sectional view illustrating a part of a process of manufacturing the display apparatus 1 of FIG. 11. In detail, FIG. 17 is a schematic cross-sectional view illustrating a process of preparing the display panel 10 of the display apparatus 1 of FIG. 11. A method of manufacturing the display apparatus according to the present embodiment may correspond to a modified embodiment of the method of manufacturing the display apparatus described above with reference to FIGS. 12 and 13. Thus, hereinafter, differences from the method of manufacturing the display apparatus described above with reference to FIGS. 12 and 13 are mainly described. In FIG. 17, the same reference numerals as in FIGS. 12 and 13 denote the same components as in FIGS. 12 and 13, and thus, their descriptions are not repeated.

According to the method of manufacturing the display apparatus according to the present embodiment, the display panel 10 may include the first area A1, the second area A2, and the bending area BA. The first pixel PX1 may be arranged in the first area A1, the second pixel PX2 may be arranged in the bending area BA, and the pad portion PD and the connection line CL may be arranged in the second area A2. The display panel 10 may include the first panel surface 10S1 and the second panel surface 10S2 positioned at the opposite side to the first panel surface 10S1. The first lower protective layer LPL1 may be attached to the second panel surface 10S2 in the first area A1 and the second lower protective layer LPL2 may be attached to the second panel surface 10S2 in the second area A2. The lower cover panel CP may be attached below the first lower protective layer LPL1, and the spacer SP may be attached below the lower cover panel CP.

The display panel 10 according to an embodiment may include the optical functional layer PO which is attached onto the display panel 10, and the cover window CW which is attached to the optical functional layer PO by using the adhesive layer AD. The optical functional layer PO may be attached onto the display panel 10 by the adhesive member. The adhesive member may not be limited to particular types and any adhesive material known in the art may be used as the adhesive member. For example, the adhesive member may include an OCA or a PSA. Also, as the connection line CL may be disposed in the second area A2, a visible area of the non-display area may be reduced.

As explained above, the display apparatus and the method of manufacturing the display apparatus according to an embodiment may reduce a visible area of the non-display area. However, the scope of the present disclosure is not limited to these effects as described above.

It should be understood that embodiments described herein should be considered in a descriptive sense only and not for purposes of limitation. Descriptions of features or aspects within each embodiment should typically be considered as available for other similar features or aspects in other embodiments. While the present disclosure has been described with reference to the drawings and embodiments thereof, it will be understood by one of ordinary skill in the art that various changes in form and details may be made thereto without departing from the spirit and scope of the present disclosure as set forth in following claims.

What is claimed is:

1. A display apparatus comprising a display panel, the display panel comprising:
a first area, a second area, and a bending area between the first area and the second area;
a first pixel arranged in the first area; and
a second pixel arranged in the bending area,
wherein the display panel further comprises a first panel surface and a second panel surface that is at an opposite side to the first panel surface,
the display panel is bent in the bending area with respect to a bending axis extending in a first direction, and
the second panel surface in the first area is arranged to face the second panel surface in the second area.

2. The display apparatus of claim 1, wherein the display panel further comprises:
a pad portion arranged in the second area; and
a connection line electrically connecting the first pixel and the second pixel to the pad portion,
wherein the connection line is arranged in the second area.

3. The display apparatus of claim 1, wherein a radius of curvature of the bending area is in a range of about 0.2 mm to about 0.4 mm.

4. The display apparatus of claim 1, further comprising:
a first lower protective layer arranged on the second panel surface in the first area; and
a second lower protective layer arranged on the second panel surface in the second area.

5. The display apparatus of claim 4, wherein an end of the second lower protective layer is in contact with the bending area.

6. The display apparatus of claim 4, wherein an end of the second lower protective layer adjacent to the bending area is spaced apart from the bending area.

7. The display apparatus of claim 6, wherein the second lower protective layer is not disposed on the second panel surface in a portion of the second area adjacent to the bending area.

8. The display apparatus of claim 4, further comprising:
a lower cover panel disposed below the first lower protective layer; and
a spacer disposed below the lower cover panel.

9. The display apparatus of claim 8, wherein the bending area, the first lower protective layer, the lower cover panel, the spacer, and the second lower protective layer define a space.

10. The display apparatus of claim 9, further comprising a filling member filling the space.

11. The display apparatus of claim 1, further comprising:
a cover window disposed above the display panel;
an optical functional layer disposed between the display panel and the cover window; and
an adhesive layer disposed between the optical functional layer and the cover window.

12. A method of manufacturing a display apparatus, the method comprising:
preparing a display panel comprising a first area, a second area, a bending area between the first area and the second area, a first pixel arranged in the first area, and a second pixel arranged in the bending area; and
bending the display panel in the bending area with respect to a bending axis extending in a first direction,
wherein the display panel further comprises a first panel surface and a second panel surface that is at an opposite side to the first panel surface, and
the second panel surface in the first area faces the second panel surface in the second area after bending the display panel.

13. The method of claim 12, wherein the display panel further comprises a pad portion arranged in the second area and a connection line electrically connecting the first pixel and the second pixel to the pad portion, and
wherein the connection line is arranged in the second area.

14. The method of claim 12, wherein a radius of curvature of the bending area is in a range of about 0.2 mm to about 0.4 mm after bending the display panel.

15. The method of claim 12, wherein the display panel further comprises:
a first lower protective layer attached to the second panel surface in the first area; and
a second lower protective layer attached to the second panel surface in the second area.

16. The method of claim 15, wherein an end of the second lower protective layer is in contact with the bending area.

17. The method of claim 15, wherein an end of the second lower protective layer adjacent to the bending area is spaced apart from the bending area.

18. The method of claim 17, wherein the second lower protective layer is not disposed on the second panel surface in a portion of the second area adjacent to the bending area.

19. The method of claim 15, wherein the display panel further comprises:
a lower cover panel attached below the first lower protective layer; and
a spacer attached below the lower cover panel.

20. The method of claim 19, further comprising:
filling a space defined by the bending area, the first lower protective layer, the lower cover panel, the spacer, and the second lower protective layer with a material for forming a filling member; and
irradiating ultraviolet rays to the material for forming the filling member.

21. The method of claim 12, wherein the display panel further comprises:
an optical functional layer attached onto the display panel; and
a cover window attached onto the optical functional layer by an adhesive layer.
